(19) United States
(12) Patent Application Publication
(10) Pub. No.: US 2021/0373052 A1
(43) Pub. Date: Dec. 2, 2021

(54) ERROR WARNING MODULE

(71) Applicants: Chun-Sheng HUNG, Taoyuan City (TW); Chien-Hsing HUANG, Taoyuan City (TW); Chi-Chiao CHENG, Taoyuan City (TW); Chao-Ming NIEN, Taoyuan City (TW)

(72) Inventors: Chun-Sheng HUNG, Taoyuan City (TW); Chien-Hsing HUANG, Taoyuan City (TW); Chi-Chiao CHENG, Taoyuan City (TW); Chao-Ming NIEN, Taoyuan City (TW)

(21) Appl. No.: 17/325,249

(22) Filed: May 20, 2021

(30) Foreign Application Priority Data
May 26, 2020 (TW) 109117488

(51) Int. Cl. G01R 19/165; G01R 19/00; G01R 19/30

(52) U.S. Cl. CPC G01R 19/16528; G01R 19/0069; G01R 19/1659; G01R 19/16533; G01R 19/30

(57) ABSTRACT

Herein disclosed is an error warning module, installed in an electronic device, comprising a detection unit and a processing unit. The detection unit detects a current or a voltage being transmitted by the electronic device to generate a current detection signal or a voltage detection signal. The processing unit, electrically connected to the detection unit, determines whether a current detection value indicated by the current detection signal exceeds a current setting range, or whether a voltage detection value indicated by the voltage detection signal exceeds a voltage setting range. When the current detection value exceeds the current setting range or the voltage detection value exceeds the voltage setting range, the processing unit generates a warning signal.

### CROSS REFERENCE TO RELATED APPLICATION

The present application claims priority to Taiwan patent application Serial No. 109117488 filed on May 26, 2020, the entire content of which is incorporated by reference to this application.

### BACKGROUND OF THE INVENTION

### 1. Field of the Invention

The present invention pertains to an error warning module, more specifically to an error warning module installed in an electronic device.

### 2. Description of the Prior Art

In general, when electronic devices transmit power or signals, transmission errors will inevitably be included in the transmitted power or signals. For example, a user can set a power supply to provide a current of 10 amps, person having ordinary skill in the art can understand that the power supply may output 10 amps but with the transmission error (slightly more or less than 10 amps) due to various non-ideal factors, such as 9 to 11 amps. Although the transmission error within the acceptable range can be tolerated in the first place, when the electronic device is used for a period of time, however, it is possible that due to the non-ideal factors, the transmission error will become larger and larger. Then, the electronic device needs to be calibrated to ensure that the power or signal can be transmitted correctly.

In practice, it is time-consuming and laborious for engineers to calibrate a plurality of electronic devices, it will undoubtedly increase the burden on the engineers. Accordingly, the industry needs a new calibration mechanism for electronic devices to reduce the burden of manpower.

### SUMMARY OF THE INVENTION

The present invention provides an error warning module, which can be installed in an electronic device. When the transmission error of the electronic device exceeds a threshold value, the error warning module can automatically send out a warning signal, which can save the user's labor for inspecting the electronic device one by one.

The present invention discloses an error warning module, installed in an electronic device, comprising a detection unit and a processing unit. The detection unit detects a current or a voltage being transmitted by the electronic device to generate a current detection signal or a voltage detection signal. The processing unit, electrically connected to the detection unit, determines whether a current detection value indicated by the current detection signal exceeds a current setting range, or whether a voltage detection value indicated by the voltage detection signal exceeds a voltage setting range. When the current detection value exceeds the current setting range or the voltage detection value exceeds the voltage setting range, the processing unit generates a warning signal.

In some embodiments, when the electronic device is an electronic load device, the detection unit may detect the current or the voltage being drawn by the electronic load device to generate the current detection signal or the voltage detection signal. The current setting range may be related to a preset load current value of the electronic load device, and when the current detection value deviates from the preset load current value by a first threshold value, the processing unit may determine the current detection value exceeds the current setting range, and then the warning signal is generated. The voltage setting range may be related to a preset load voltage value of the electronic load device, and when the voltage detection value deviates from the preset load voltage value by a second threshold value, the processing unit may determine the voltage detection value exceeds the voltage setting range, and then the warning signal is generated.

In some embodiments, when the electronic device is a power supply, the detection unit may detect the current or the voltage being output by the power supply to generate the current detection signal or the voltage detection signal. Besides, the current setting range may be related to a preset supply current value of the power supply, and when the current detection value deviates from the preset supply current value by a third threshold value, the processing unit may determine the current detection value exceeds the current setting range, and then the warning signal is generated. And, the voltage setting range may be related to a preset supply voltage value of the power supply, and when the voltage detection value deviates from the preset supply voltage value by a fourth threshold value, the processing unit determines the voltage detection value exceeds the voltage setting range, and then the warning signal is generated.

In some embodiments, temperature at an installation location of the detection unit may be less than an average temperature in the electronic device. The detection unit may further repeatedly detect the current or the voltage being transmitted by the electronic device during a detection period, and may repeatedly generate a plurality of current detection signals or voltage detection signals during the detection period. Besides, the processing unit may determine whether the current detection value indicated by each current detection signal exceeds the current setting range, and when the number of times that the current detection value exceeds the current setting range reaches a fifth threshold value within the detection period, the processing unit may generate the warning signal. And, the processing unit may determine whether the voltage detection value indicated by each voltage detection signal exceeds the voltage setting range, and when the number of times that the voltage detection value exceeds the voltage setting range reaches a sixth threshold value within the detection period, the processing unit may generate the warning signal.

Based on the above, the error warning module provided by the present invention can be installed in an electronic device, and automatically detects whether there is a transmission error in the current or voltage output or received by the electronic device. When the transmission error of the output or received current or voltage of the electronic device exceeds a preset threshold, the error warning module can automatically send a warning signal, which can save the user's labor for inspecting the electronic device one by one.

### BRIEF DESCRIPTION OF THE APPENDED DRAWINGS

FIG. 1 is a schematic diagram of the error warning module in accordance with an embodiment of the present invention.

### DETAILED DESCRIPTION OF THE INVENTION

The features, objections, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

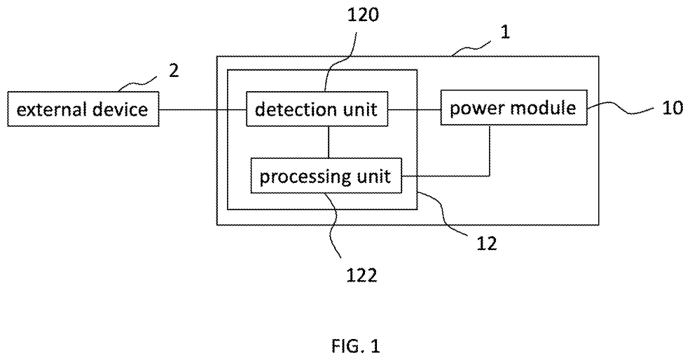

Please refer to FIG. 1, FIG. 1 is a schematic diagram of the error warning module in accordance with an embodiment of the present invention. As shown in FIG. 1, an electronic device 1 may comprise a power module 10 and an error warning module 12, and the power module 10 may be used to perform main functions of the electronic device 1. For example, when the electronic device 1 is an electronic load device, an external device 2 to which the electronic device 1 is connected may be a power supply. Here, the power module 10 can be a module consuming power and receiving current or voltage from the external device 2, and the power module 10 can be a load to the external device 2. On the other hand, when the electronic device 1 is a power supply, the external device 2 to which the electronic device 1 is connected can be regarded as a kind of load. Here, the power module 10 can be a module supplying power and outputting current to the external device 2, and the power module 10 can be a power supply to the external device 2.

In addition, the error warning module 12 may comprise a detection unit 120 and a processing unit 122. The detection unit 120 may be connected in series between the power module 10 and the external device 2, and the processing unit 122 may be electrically connected to the power module 10 and the detection unit 120. In practice, the detection unit 120 can be used to detect the current or the voltage transmitted between the electronic device 1 and the external device 2. This embodiment does not limit the direction of the current. For example, the electronic device 1 can output the current or the voltage to the external device 2, or the electronic device 1 can receive the current or the voltage from the external device 2. In addition, the detection unit 120 is disposed or installed inside the electronic device 1, and the installation location of the detection unit 120 should be a location with good heat dissipation, so as to prevent the detection unit 120 from being affected by temperature and causing detection errors. For example, the installation location of the detection unit 120 will be far away from other components in the electronic device 1 that are prone to generate heat, so that the temperature of the installation location of the detection unit 120 will be lower than an average temperature in the electronic device 1.

Taking the aforementioned electronic device 1 which can be the electronic load device as an example, since the power module 10 is used to consume the power provided by the external device 2, the detection unit 120 will detect the current or the voltage from the external device 2, and generate a current detection signal or a voltage detection signal. When the detection unit 120, as an example, is used to detect current, the user can set the current to be drawn by the power module 10, e.g., a preset load current value, through the control interface (not shown in FIG. 1). Of course, this embodiment does not limit how to set the power module 10. Setting commands from the user through the control interface can be received by the processing unit 122, and then the processing unit 122 can set the power module 10. For example, the user can set the power module 10 to draw a current of 10 amperes, i.e., the preset load current value is 10 amperes, and then when the power module 10 is activated, the detection unit 120 will detect a current detection value that actually drawn by the power module 10.

Here, since the electronic device 1 does not necessarily start to transmit current as soon as being activated, the detection unit 120 may initially be in a standby mode or non-intensive detection mode (with a longer sampling interval). In addition, the current detection value actually detected by the detection unit 120 can be recorded in the current detection signal. Assuming that the detection unit 120 actually detects only 9 amperes, then the value of 9 amperes can be the current detection value. Then, the processing unit 122 can receive the current detection signal from the detection unit 120, and know that the current detection value is 9 amperes. Since the processing unit 122 knows the preset load current value (10 amperes) of the power module 10 at this time, the processing unit 122 can determine whether the current detection value exceeds a current setting range. In an example, assuming that the current setting range is known to be 9.5 amperes to 10.5 amperes, the processing unit 122 can determine that the current detection value, 9 amperes, below the lower limit of the current setting range, so the processing unit 122 will generate a warning signal to indicate that the electronic device 1 is currently under abnormal loading conditions. In other words, when the current detection value deviates from the preset load current value by a first threshold value (0.5 ampere in this example), the processing unit 122 can determine that the current detection value exceeds the current setting range. In this embodiment, the current setting range is not particularly limited, the current setting range may be regulated by the specification of the electronic device 1, or be set by the user.

Of course, in order to make the detection more accurate, the processing unit 122 may repeatedly receive a plurality of current detection signals within a detection period. For example, assuming that the detection unit 120 can detect ten times within 1 millisecond, the processing unit 122 can receive the current detection signals of the ten times. And, the processing unit 122 can determine how many of the current detection values corresponding to the current detection signals of the ten times exceed the current setting range. The user can set how many times the processing unit 122 detects the abnormal current detection value before generating the warning signal, that means a warning threshold (fifth threshold) can be determined by the user himself. In one example, the user can set the warning threshold to three, that is, if three current detection values corresponding to current detection signals exceed the current setting range within the detection period, the processing unit 122 can determine the electronic device 1 is currently under abnormal load conditions, so the processing unit 122 will generate the warning signal.

This embodiment does not limit the detection unit 120 to detect current, and the detection unit 120 can also be used to detect voltage. For example, the user can also, by using the control interface (not shown in FIG. 1), set the power module 10 to draw 10 volts, i.e., a preset load voltage value is 10 volts, and a voltage detection value actually detected by the detection unit 120 can be recorded in a voltage detection signal. Assuming that the detection unit 120 actually detects 9 volts, the value of 9 volts can be regarded as the voltage detection value. In addition, the processing unit 122 can also receive the voltage detection signal from the detection unit 120, and know that the voltage detection value is 9 volts. Besides, assuming that the processing unit 122 knows that the preset load voltage value of the power module 10 is 10 volts. Therefore, the processing unit 122 can determine whether the voltage detection value exceeds the voltage setting range. The same as the previous example, assuming that the voltage setting range is known to be 9.5 volts to 10.5 volts, the processing unit 122 can also determine that 9 volts is too low and below the lower limit of the voltage setting range, so that the processing unit 122 will generate a warning signal to warn that the electronic device 1 is currently loaded abnormally. In other words, when the voltage detection value deviates from the preset load voltage value by a second threshold value (0.5 volt in this example), the processing unit 122 can determine that the voltage detection value exceeds the voltage setting range.

Similarly, the processing unit 122 can repeatedly receive a plurality of voltage detection signals within a detection period. For example, assuming that the detection unit 120 can detect ten times within 1 millisecond, the processing unit 122 can receive ten voltage detection signals and determine how many of the voltage detection values corresponding to the voltage detection signals exceed the voltage setting range, and a warning threshold value (a sixth threshold value) can also be determined by the user.

On the other hand, taking the aforementioned electronic device 1 as a power supply as another example, since the power module 10 is used for supplying power required by the external device 2, the detection unit 120, in this example, detects the current output from the power module 10 to the external device 2 and then generates a current detection signal. In practice, the user can set a preset supply current value, which is the current to be output by the power module 10, through a control interface (not shown). Similarly, the user can set the power module 10 to output a current of 10 amperes, and then when the power module 10 starts to work, the detection unit 120 detects the actual current value, which is a current detection value, output by the power module 10. Here, the current detection value actually detected by the detection unit 120 can be recorded in the current detection signal. For example, assuming that the detection unit 120 actually detects only 9 amperes, then the value of 9 amperes can be the current detection value.

Same as the previous example, assuming that the current setting range is known to be 9.5 amperes to 10.5 amperes, the processing unit 122 can determine that 9 amperes is too low and below the lower limit of the current setting range, so that the processing unit 122 will generate a warning signal to indicate that the electronic device 1 currently has an abnormal output current. In other words, when the current detection value deviates from the preset supply current value by a third threshold value (0.5 ampere in this example), the processing unit 122 can determine that the current detection value exceeds the current setting range.

Take the detection unit 120 for detecting voltage as an example. Since the detection unit 120 can detect the voltage output from the power module 10 to the external device 2, it can generate a voltage detection signal. Similarly, the user can set a preset supply voltage value to be output by the power module 10 through the control interface (not shown). In practice, the user can set the power module 10 to output a current of 10 volts, and then when the power module 10 starts to work, the detection unit 120 detects the voltage value actually outputted by the power module 10. Here, a voltage detection value actually detected by the detection unit 120 can be recorded in the voltage detection signal. Assuming that the detection unit 120 actually detects 9 volts, then the value of 9 volts can be the voltage detection value. A voltage setting range can be known to be 9.5 volts to 10.5 volts, and the processing unit 122 can determine that 9 volts is too low and below the lower limit of the voltage setting range. The processing unit 122 will generate a warning signal to warn that the electronic device 1 currently has an abnormal output voltage. In other words, when the voltage detection value deviates from the preset supply voltage value by a fourth threshold value (0.5 volt in this example), the processing unit 122 can determine that the voltage detection value exceeds the voltage setting range.

In summary, the error warning module provided by the present invention can be installed in an electronic device, and automatically detects whether there is a transmission error in the current or voltage output or received by the electronic device. When the transmission error of the output or received current or voltage of the electronic device exceeds a preset threshold, the error warning module can automatically send a warning signal, which can save the user's labor for inspecting the electronic device one by one.

What is claimed is:

1. An error warning module, installed in an electronic device, comprising:
a detection unit for detecting a current or a voltage being transmitted by the electronic device to generate a current detection signal or a voltage detection signal; and
a processing unit, electrically connected to the detection unit, for determining whether a current detection value indicated by the current detection signal exceeds a current setting range, or whether a voltage detection value indicated by the voltage detection signal exceeds a voltage setting range;
wherein when the current detection value exceeds the current setting range or the voltage detection value exceeds the voltage setting range, the processing unit generates a warning signal.

2. The error warning module according to claim 1, wherein when the electronic device is an electronic load device, the detection unit detects the current or the voltage being drawn by the electronic load device to generate the current detection signal or the voltage detection signal.

3. The error warning module according to claim 2, wherein the current setting range is related to a preset load current value of the electronic load device, and when the current detection value deviates from the preset load current value by a first threshold value, the processing unit determines the current detection value exceeds the current setting range, and then the warning signal is generated.

4. The error warning module according to claim 2, wherein the voltage setting range is related to a preset load voltage value of the electronic load device, and when the voltage detection value deviates from the preset load voltage value by a second threshold value, the processing unit determines the voltage detection value exceeds the voltage setting range, and then the warning signal is generated.

5. The error warning module according to claim 1, wherein when the electronic device is a power supply, the detection unit detects the current or the voltage being output by the power supply to generate the current detection signal or the voltage detection signal.

6. The error warning module according to claim 5, wherein the current setting range is related to a preset supply current value of the power supply, and when the current detection value deviates from the preset supply current value by a third threshold value, the processing unit determines the current detection value exceeds the current setting range, and then the warning signal is generated.

7. The error warning module according to claim 5, wherein the voltage setting range is related to a preset supply voltage value of the power supply, and when the voltage detection value deviates from the preset supply voltage value by a fourth threshold value, the processing unit determines the voltage detection value exceeds the voltage setting range, and then the warning signal is generated.

8. The error warning module according to claim 1, wherein temperature at an installation location of the detection unit is less than an average temperature in the electronic device.

9. The error warning module according to claim 1, wherein the detection unit further repeatedly detects the current or the voltage being transmitted by the electronic device during a detection period, and repeatedly generates a plurality of current detection signals or voltage detection signals during the detection period.

10. The error warning module according to claim 9, wherein the processing unit determines whether the current detection value indicated by each current detection signal exceeds the current setting range, and when the number of times that the current detection value exceeds the current setting range reaches a fifth threshold value within the detection period, the processing unit generates the warning signal.

11. The error warning module according to claim 9, wherein the processing unit determines whether the voltage detection value indicated by each voltage detection signal exceeds the voltage setting range, and when the number of times that the voltage detection value exceeds the voltage setting range reaches a sixth threshold value within the detection period, the processing unit generates the warning signal.
